(19) United States
(12) Patent Application Publication
(10) Pub. No.: US 2025/0105124 A1
(43) Pub. Date: Mar. 27, 2025

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Toyokazu SHIBATA, Kawasaki Kanagawa (JP)

(21) Appl. No.: 18/601,346

(22) Filed: Mar. 11, 2024

(30) Foreign Application Priority Data
Sep. 21, 2023 (JP) 2023-156394

(51) Int. Cl. H01L 23/498; H01L 23/00

(52) U.S. Cl. CPC H01L 23/49838; H01L 24/32; H01L 2224/32245; H01L 2924/181

(57) ABSTRACT

A semiconductor device includes a first conductive member, a second conductive member, a semiconductor chip, a connection plate, a first bonding member, a second bonding member, and a resin part. The second conductive member includes a first part and a second part. The second part includes a lead part. The semiconductor chip is located between the first part and the first conductive member. The connection plate is located between the semiconductor chip and the first part. The first bonding member is positioned between the semiconductor chip and the connection plate. The second bonding member is positioned between the first part and the connection plate. The resin part covers the semiconductor chip, the connection plate, and the first part. The resin part does not cover a portion of the lead part and a portion of the first conductive member.

### CROSS-REFERENCE TO RELATED APPLICATIONS

This application is based upon and claims the benefit of priority from Japanese Patent Application No.2023-156394, filed on Sep. 21, 2023; the entire contents of which are incorporated herein by reference.

### FIELD

Embodiments relate to a semiconductor device.

### BACKGROUND

There is a semiconductor device (a semiconductor package) in which a semiconductor chip is sealed. For example, a conductive member that includes leads is connected to the semiconductor chip by a conductive bonding member such as solder, etc. In such a semiconductor device, there are cases where delamination occurs at a bonding member electrically connecting the semiconductor chip and the conductive member. For example, the load from a jig in a manufacturing process of the semiconductor device is transferred via the leads, and delamination occurs in the solder on the semiconductor chip. As a result, defects that degrade the characteristics of the semiconductor device may occur.

### BRIEF DESCRIPTION OF THE DRAWINGS

FIG. 1 is a schematic perspective view illustrating a semiconductor device according to a first embodiment;

FIG. 2 is a schematic plan view illustrating the semiconductor device according to the first embodiment;

FIG. 3 is a schematic perspective view illustrating a portion of the semiconductor device according to the first embodiment;

FIG. 4 is a schematic plan view illustrating a portion of the semiconductor device according to the first embodiment;

FIG. 5 is a schematic cross-sectional view illustrating a portion of the semiconductor device according to the first embodiment;

FIG. 6A is a schematic cross-sectional view illustrating a semiconductor device according to a reference example;

FIG. 6B is a schematic cross-sectional view illustrating the semiconductor device according to the embodiment;

FIG. 7 is a graph illustrating characteristics of the semiconductor devices;

FIGS. 8A to 8C are schematic side views illustrating a mold process;

FIG. 9 is a schematic cross-sectional view illustrating a portion of another semiconductor device according to the first embodiment;

FIG. 10 is a schematic plan view illustrating a portion of a semiconductor device according to a second embodiment;

FIG. 11 is a schematic cross-sectional view illustrating a portion of the semiconductor device according to the second embodiment;

FIGS. 12A to 12C are schematic cross-sectional views illustrating manufacturing processes of the second conductive member according to the embodiment; and

FIG. 13 is a schematic cross-sectional view illustrating a portion of another semiconductor device according to the second embodiment.

### DETAILED DESCRIPTION

A semiconductor device according to one embodiment, includes a first conductive member, a second conductive member, a semiconductor chip, a connection plate, a first bonding member, a second bonding member, and a resin part. The second conductive member includes a first part and a second part. The first part is separated from the first conductive member in a first direction. The second part extends from an end portion of the first part in a second direction crossing the first direction. The second part includes a lead part. The semiconductor chip is located between the first part and the first conductive member in the first direction. The semiconductor chip is electrically connected with the first conductive member. The connection plate is located between the semiconductor chip and the first part in the first direction. The connection plate is conductive. The first bonding member is positioned between the semiconductor chip and the connection plate. The first bonding member electrically connects the semiconductor chip and the connection plate. the first bonding member is conductive. The second bonding member is positioned between the first part and the connection plate. The second bonding member electrically connects the first part and the connection plate. The second bonding member is conductive. The resin part covers the semiconductor chip, the connection plate, and the first part. The resin part does not cover a portion of the lead part and a portion of the first conductive member.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

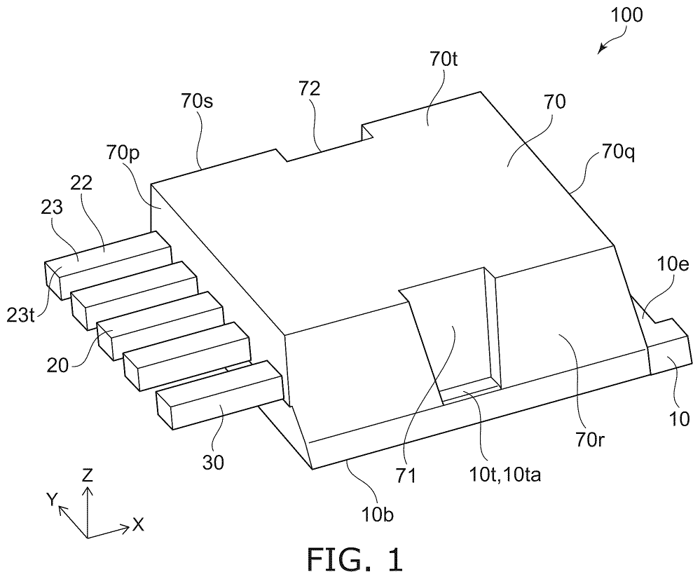

FIG. 1 is a schematic perspective view illustrating a semiconductor device according to a first embodiment.

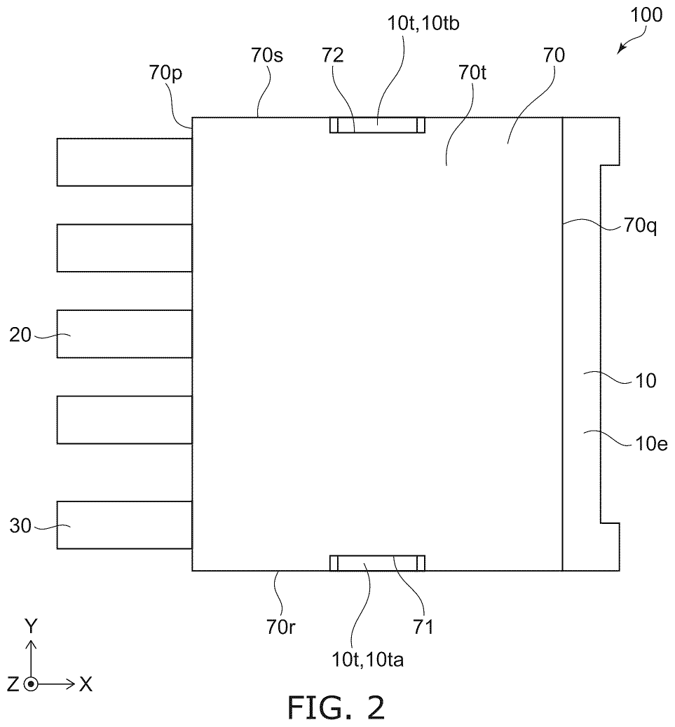

FIG. 2 is a schematic plan view illustrating the semiconductor device according to the first embodiment.

As illustrated in FIGS. 1 and 2, the semiconductor device 100 according to the embodiment includes a first conductive member 10, a second conductive member 20, a third conductive member 30, and a resin part 70.

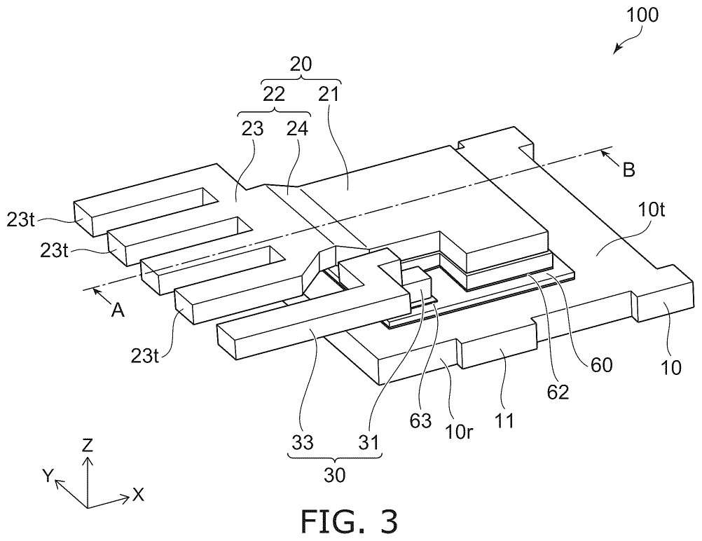

FIG. 3 is a schematic perspective view illustrating a portion of the semiconductor device according to the first embodiment.

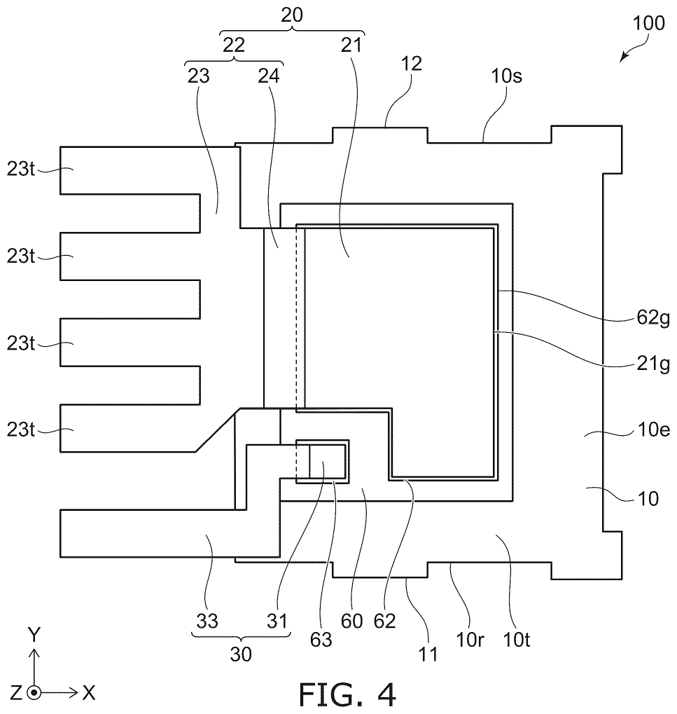

FIG. 4 is a schematic plan view illustrating a portion of the semiconductor device according to the first embodiment.

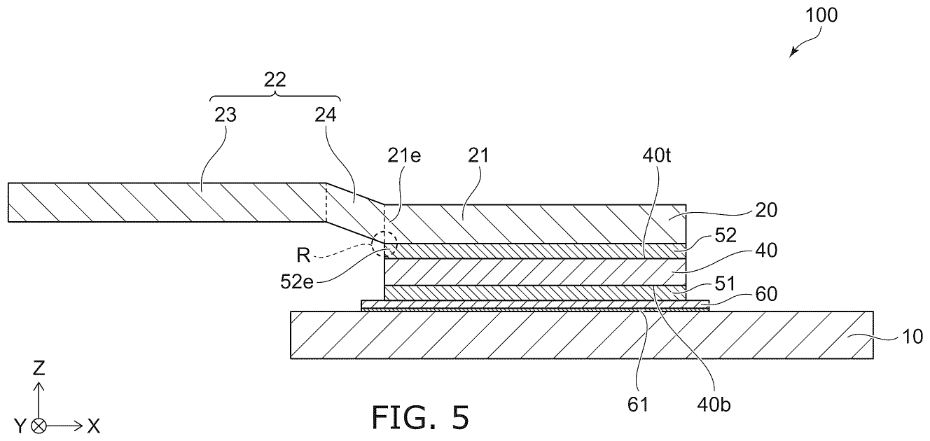

FIG. 5 is a schematic cross-sectional view illustrating a portion of the semiconductor device according to the first embodiment.

The resin part 70 is not illustrated in FIGS. 3 to 5 to show the structure inside the resin part 70. FIG. 5 shows a cross section along line A-B illustrated in FIG. 3.

For example, as illustrated in FIG. 5, the semiconductor device 100 further includes a semiconductor chip 60, a connection plate 40, a first bonding member 51, and a second bonding member 52.

The first conductive member 10 has a substantially rectangular flat plate shape extending along the X-Y plane, and is conductive. The second conductive member 20 includes a conductive first part 21 and a conductive second part 22.

An XYZ orthogonal coordinate system is used in the description of embodiments. The direction from the first conductive member 10 toward the first part 21 is taken as a Z-direction (a first direction). Two mutually-orthogonal directions perpendicular to the Z-direction are taken as an X-direction (a second direction) and a Y-direction (a third direction). In the description, the direction from the first conductive member 10 toward the first part 21 is called “up/upward/above”, and the opposite direction is called “down/downward/below”. These directions are based on the relative positional relationship between the first conductive member 10 and the first part 21, and are independent of the direction of gravity. The Z-direction is, for example, a direction perpendicular to the upper surface of the first conductive member 10.

For example, as illustrated in FIG. 5, the first part 21 is separated from the first conductive member 10 in the Z-direction. The first part 21 has a conductive flat plate shape extending along the X-Y plane. The second part 22 extends from an end portion 21e in the X-direction of the first part 21. The second part 22 is conductive and includes a lead part 23 and an intermediate part 24.

The lead part 23 extends in the X-direction. The lead part 23 branches into multiple terminals 23t extending in the X-direction at the distal side (the side opposite to the first part 21) (see FIGS. 3 and 4). The intermediate part 24 connects the lead part 23 and the end portion 21e of the first part 21. The intermediate part 24 is positioned between the lead part 23 and the first part 21 in the X-direction. The intermediate part 24 is inclined downward from the lead part 23 toward the first part 21.

The semiconductor chip 60 is positioned between the first conductive member 10 and the first part 21 in the Z-direction. “A first component is between a second component and a third component in a direction” means that, in other words, the position in the direction of the first component is between the position in the direction of the second component and the position in the direction of the third component. The semiconductor chip 60 is electrically connected with the first conductive member 10.

In the example, the semiconductor chip 60 is a semiconductor chip including a vertical MOSFET (Metal-Oxide-Semiconductor Field-Effect Transistor). For example, as illustrated in FIG. 5, the semiconductor chip 60 includes an electrode 61 located at the lower surface of the semiconductor chip 60. The electrode 61 is, for example, the drain electrode of the MOSFET. The electrode 61 is formed over the entire lower surface of the semiconductor chip 60.

For example, a not-illustrated conductive bonding member (e.g., solder) is located between the first conductive member 10 and the electrode 61. The bonding member contacts the first conductive member 10 and the electrode 61 and electrically connects the first conductive member 10 and the electrode 61.

The connection plate 40 is positioned between the semiconductor chip 60 and the first part 21 in the Z-direction. The connection plate 40 is conductive and has a flat plate shape extending along the X-Y plane. As illustrated in FIG. 5, the connection plate 40 includes a lower surface 40b and an upper surface 40t. The lower surface 40b contacts the first bonding member 51. The upper surface 40t contacts the second bonding member 52.

A member other than the connection plate 40 such as the resin part 70 or the like is not located between the upper surface 40t and the lower surface 40b of the connection plate 40. That is, the connection plate 40 is continuous from the upper surface 40t to the lower surface 40b between the upper surface 40t and the lower surface 40b. In other words, the connection plate 40 is continuous in the Z-direction from the upper surface 40t to the lower surface 40b in the area overlapping the upper surface 40t and the lower surface 40b in the Z-direction.

A plate (a flat plate) includes not only a shape of which the surfaces (the upper surface 40t, the lower surface 40b, etc.) are flat planes, but also may be a shape in which unevennesses are provided in the surfaces.

The first bonding member 51 is positioned between the semiconductor chip 60 and the connection plate 40. The first bonding member 51 is conductive and electrically connects the semiconductor chip 60 and the connection plate 40. The first bonding member 51 contacts the semiconductor chip 60 and the connection plate 40.

More specifically, the first bonding member 51 contacts an electrode 62 of the semiconductor chip 60 (see FIG. 4) and the connection plate 40. As illustrated in FIG. 4, the electrode 62 and an electrode 63 are located at portions of the upper surface of the semiconductor chip 60. The area of the electrode 62 is greater than the area of the electrode 63. The electrode 62 is, for example, the source electrode of the MOSFET; and the electrode 63 is, for example, the gate electrode of the MOSFET.

As illustrated in FIG. 5, the second bonding member 52 is positioned between the first part 21 and the connection plate 40. The second bonding member 52 is conductive and electrically connects the first part 21 and the connection plate 40. The second bonding member 52 contacts the first part 21 and the connection plate 40.

For example, as illustrated in FIG. 4, the planar shape of the first part 21 is substantially the same as the planar shape of the electrode 62. More specifically, when viewed in plan as in FIG. 4, an outer edge 21g of the first part 21 is positioned inward of an outer edge 62g of the electrode 62, and extends along the outer edge 62g of the electrode 62. The area of the first part 21 is less than the area of the electrode 62.

Similarly to the planar shape of the first part 21, the planar shape of the connection plate 40, the planar shape of the first bonding member 51, and the planar shape of the second bonding member 52 each are substantially the same as the planar shape of the electrode 62. When viewed in plan, similarly to the outer edge 21g of the first part 21, the outer edge of the connection plate 40, the outer edge of the first bonding member 51, and the outer edge of the second bonding member 52 each are positioned inward of the outer edge 62g of the electrode 62 and extend along the outer edge 62g of the electrode 62.

The planar shape of the connection plate 40, the planar shape of the first bonding member 51, and the planar shape of the second bonding member 52 each may be the same as the planar shape of the first part 21. When viewed in plan, the outer edge of the connection plate 40, the outer edge of the first bonding member 51, and the outer edge of the second bonding member 52 each may be at the same position as the outer edge of the first part 21.

For example, as illustrated in FIGS. 3 and 4, the third conductive member 30 includes a connection part 31, and a lead part 33 electrically connected with the connection part 31. A not-illustrated conductive bonding member (e.g., solder) is located between the electrode 63 and the connection part 31. The bonding member contacts the electrode 63 and the connection part 31 and electrically connects the electrode 63 and the connection part 31. The lead part 33 is arranged with the lead part 23 in the Y-direction and extends in the X-direction.

Thus, the semiconductor chip 60, the first bonding member 51, the connection plate 40, the second bonding member 52, the first part 21, and the connection part 31 are stacked and covered with the resin part 70 illustrated in FIGS. 1 and 2.

As illustrated in FIG. 1, the resin part 70 includes an upper surface 70t, a side surface 70p, a side surface 70q, a side surface 70r, and a side surface 70s. The side surface 70q faces the X-direction. The side surface 70p faces away from the side surface 70q. The side surface 70s faces the Y-direction. The side surface 70r faces away from the side surface 70s.

The terminal 23t of the lead part 23 of the second conductive member 20 protrudes from the side surface 70p. The terminal 23t extends from the side surface 70p toward the opposite direction of the X-direction. The resin part 70 covers the intermediate part 24 of the second conductive member 20 (see FIG. 3, etc.) but does not cover the terminal 23t of the lead part 23.

Similarly, the resin part 70 covers the connection part 31 of the third conductive member 30. The lead part 33 of the third conductive member 30 protrudes from the side surface 70p.

As illustrated in FIGS. 1 and 2, an end portion 10e in the X-direction of the first conductive member 10 extends in the X-direction from the side surface 70q. The resin part 70 does not cover the end portion 10e. Also, the resin part 70 does not cover a lower surface 10b of the first conductive member 10 (see FIG. 1).

A recess 71 (a groove) is provided in the X-direction central portion of the side surface 70r. An end portion 10ta in the Y-direction of an upper surface 10t of the first conductive member 10 is not covered with the resin part 70 at the recess 71. The recess 71 extends from the upper surface 70t of the resin part 70 to the end portion 10ta of the upper surface 10t along the Z-direction.

Similarly, a recess 72 (a groove) is provided in the X-direction central portion of the side surface 70s. An end portion 10tb of the upper surface 10t of the first conductive member 10 at the side opposite to the end portion 10ta in the Y-direction (see FIG. 2) is not covered with the resin part 70 at the recess 72. The recess 72 extends along the Z-direction from the upper surface 70t of the resin part 70 to the end portion 10tb of the upper surface 10t.

For example, the end portion 10ta of the upper surface 10t is the upper surface of a protrusion 11 of the first conductive member 10 (see FIG. 4). As illustrated in FIG. 4, the protrusion 11 is provided in a side surface 10r of the first conductive member 10. For example, the end portion 10tb of the upper surface 10t is the upper surface of a protrusion 12 of the first conductive member 10 (see FIG. 4). As illustrated in FIG. 4, the protrusion 12 is provided in a side surface 10s of the first conductive member 10. The side surface 10s faces the Y-direction; and the side surface 10r faces away from the side surface 10s.

The resin part 70 covers portions of the first conductive member 10 other than the end portion 10e, the end portion 10ta, the end portion 10tb, and the lower surface 10b.

Examples of the materials of the components of the semiconductor device 100 will now be described.

The first conductive member 10, the second conductive member 20, and the third conductive member 30 include, for example, metal materials including at least one of copper, iron, or nickel. The metal materials included in the conductive members may include, for example, an alloy of copper and iron, or an alloy of iron and nickel.

The connection plate 40 includes, for example, a metal material including at least one of copper, iron, or nickel and iron.

The metal material included in the connection plate 40 may include, for example, an alloy of copper and iron, or an alloy of iron and nickel.

The first bonding member 51 and the second bonding member 52 include, for example, solder.

The semiconductor chip 60 includes a semiconductor substrate including a semiconductor material. Examples of the semiconductor material include, for example, silicon, silicon carbide, gallium nitride, or gallium arsenide. The semiconductor substrate may include an n-type impurity (e.g., arsenic or phosphorus) and/or a p-type impurity (e.g., boron). For example, the electrical resistivity of the semiconductor substrate is greater than the electrical resistivities of the first conductive member 10, the second conductive member 20, and the third conductive member 30. The electrodes 61, 62, and 63 included in the semiconductor chip 60 include, for example, metal materials of at least one of aluminum, nickel, or copper.

Operations of the semiconductor device 100 will now be described.

For example, a positive voltage with respect to the electrode 62 (the source electrode) of the semiconductor chip 60 is applied to the electrode 61 (the drain electrode) via the first conductive member 10. The transistor is switched on and off by a voltage applied to the electrode 63 (the gate electrode) via the third conductive member 30. The transistor that is formed in the semiconductor chip 60 is switched on when the voltage of the electrode 63 with respect to the electrode 62 exceeds a threshold voltage. As a result, the on-current of the transistor flows from the first conductive member 10 toward the lead part 23 via the electrode 61, the electrode 62, the first bonding member 51, the connection plate 40, the second bonding member 52, and the first part 21. When the voltage of the electrode 63 with respect to the electrode 62 is not more than the threshold, the transistor is switched off, and the on-current does not flow.

Although a case where the semiconductor chip 60 includes a MOSFET is illustrated, the semiconductor element included in the semiconductor chip 60 is not limited thereto. For example, the semiconductor chip 60 may include an IGBT (Insulated Gate Bipolar Transistor). The electrode 61 may be the collector electrode of the IGBT; the electrode 62 may be the emitter electrode of the IGBT; and the electrode 63 may be the gate electrode of the IGBT.

According to the embodiment, by suppressing delamination of the first bonding member 51, a defect of the semiconductor device 100 such as increased on-resistance can be suppressed. The risk of a defect such as increased on-resistance or the like can be reduced.

There are cases where a force to pull the lead part 23 and the first conductive member 10 away from each other in the Z-direction is applied to the lead part 23 and the first conductive member 10. For example, before sealing the semiconductor chip 60 with the resin part 70 in the manufacturing process of the semiconductor device 100 as described below, the first conductive member 10 may be pressed downward in a state in which the position of the lead part 23 is fixed in a mold. When such a force is applied, there is a possibility that delamination of the second bonding member 52 may occur. In other words, there are cases where the second bonding member 52 delaminates from the connection plate 40 or the first part 21.

As described above, the second part 22 that extends from the end portion of the first part 21 of the lead part 23 extends in the X-direction. When a force to pull the lead part 23 and the first conductive member 10 away from each other in the Z-direction is applied with the position of such a lead part 23 in a fixed state, delamination between the second bonding member 52 and the second conductive member 20 easily occurs at, for example, a region R (an end portion 52e of the second bonding member 52 at the lead part 23 side) illustrated in FIG. 5. Thus, when delamination occurs at the second bonding member 52, the occurrence of delamination at the first bonding member 51 can be suppressed because the force applied to the first bonding member 51 is relaxed. For example, sacrificial delamination of the second bonding member 52 absorbs the load; and delamination of the first bonding member 51 is suppressed.

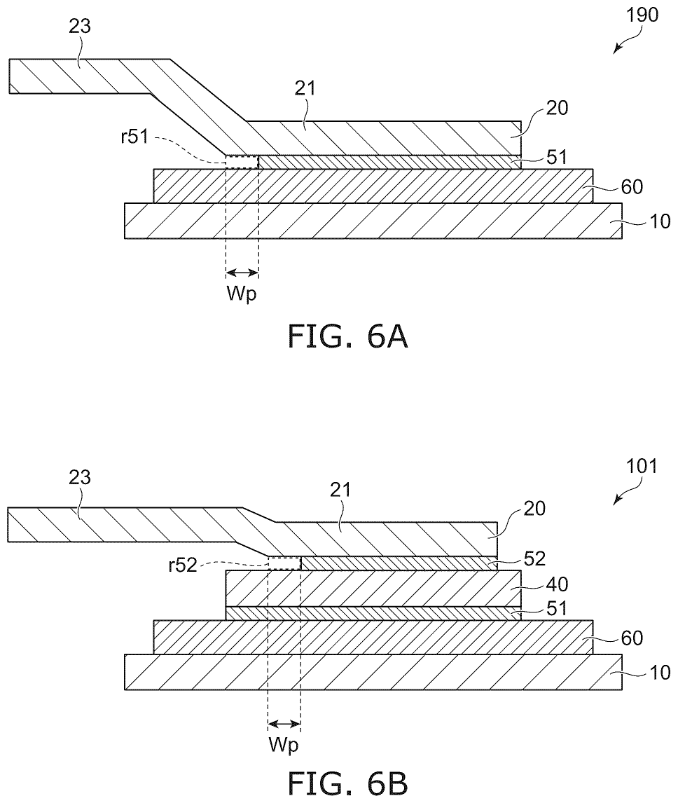

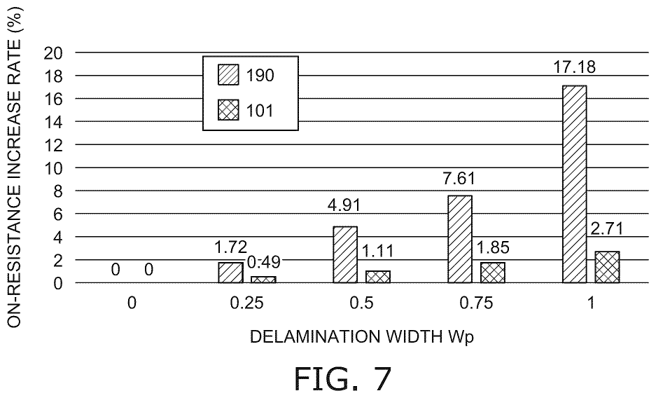

By suppressing delamination of the first bonding member 51, defects of the semiconductor device 100 such as increased on-resistance can be suppressed. This is described with reference to FIGS. 6A, 6B, and 7.

FIG. 6A is a schematic cross-sectional view illustrating a semiconductor device according to a reference example; and FIG. 6B is a schematic cross-sectional view illustrating the semiconductor device according to the embodiment.

The semiconductor device 190 of the reference example illustrated in FIG. 6A does not include the connection plate 40 and the second bonding member 52. In the semiconductor device 190, the electrode 62 of the semiconductor chip 60 is electrically connected with the first part 21 of the second conductive member 20 by the first bonding member 51. Similarly to the semiconductor device 100 described above, the semiconductor device 101 according to the embodiment illustrated in FIG. 6B includes the first conductive member 10, the semiconductor chip 60, the first bonding member 51, the connection plate 40, the second bonding member 52, and the second conductive member 20.

The on-resistance was calculated for delamination occurring as illustrated in FIG. 6A at an end portion r51 of the first bonding member 51 of the semiconductor device 190 at the lead part 23 side. The on-resistance was calculated for delamination occurring as illustrated in FIG. 6B at an end portion r52 of the second bonding member 52 of the semiconductor device 101 at the lead part 23 side. A delamination width Wp was the X-direction length of the region at which delamination of the bonding members occurred. FIG. 7 shows the calculation results.

FIG. 7 is a graph illustrating characteristics of the semiconductor devices.

FIG. 7 illustrates the on-resistance increase rate when delamination occurred, with respect to the on-resistance when delamination did not occur (Wp=0). FIG. 7 shows when the delamination width Wp was 0 mm, 0.25 mm, 0.5 mm, 0.75 mm, and 1.0 mm.

As illustrated in FIG. 7, for example, when the delamination width Wp was 0.25 mm, the on-resistance increase rate of the semiconductor device 190 was 1.72%; and the on-resistance increase rate of the semiconductor device 101 was 0.49%. For example, when the delamination width Wp was 1.0 mm, the on-resistance increase rate of the semiconductor device 190 was 17.18%; and the on-resistance increase rate of the semiconductor device 101 was 2.71%. Thus, the embodiment can suppress increased on-resistance when bonding member delamination occurs. Accordingly, the risk of defects occurring can be reduced.

For example, when delamination occurs in the first bonding member 51 of the semiconductor device 190 of the reference example, a path through which the current flows from the semiconductor chip 60 toward the first bonding member 51 becomes narrow. The on-resistance is increased thereby. On the other hand, in the semiconductor device 101, even when delamination occurs in the second bonding member 52, the path of the current flowing from the semiconductor chip 60 toward the first bonding member 51 does not become narrow. When delamination occurs in the second bonding member 52, for example, the path of the current flowing from the connection plate 40 toward the second bonding member 52 becomes narrow. It is considered that when the path of the current toward the second bonding member 52 becomes narrow, for example, the path of the current flowing through the connection plate 40 lengthens in order for the current to flow toward the second bonding member 52. Here, it is considered that the effects of the longer current path are relatively small because the connection plate 40 is conductive. It is considered that the relatively small effects suppress increased on-resistance.

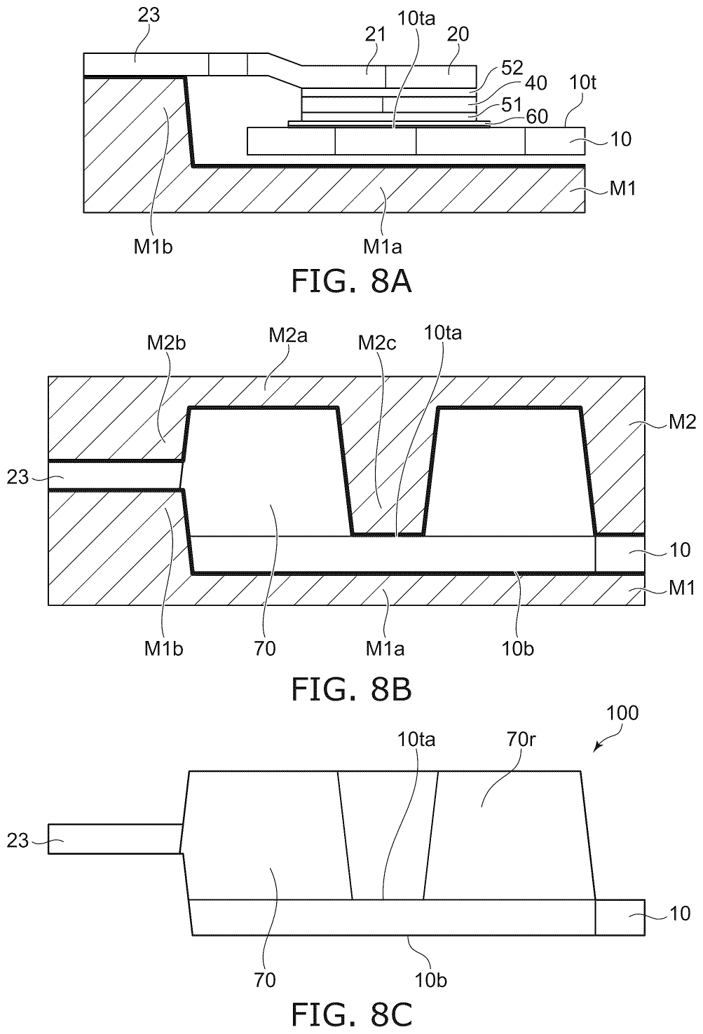

FIGS. 8A to 8C are schematic views illustrating manufacturing processes of the semiconductor device according to the first embodiment.

FIGS. 8A to 8C are schematic side views illustrating a mold process of sealing the bonded semiconductor chip 60 and the like (the first conductive member 10, the semiconductor chip 60, the connection plate 40, and the second conductive member 20) with the resin part 70.

As illustrated in FIG. 8A, the bonded semiconductor chip 60 and the like are placed above a lower die M1. The lower die M1 includes a lower part M1a, and a protrusion M1b extending upward from the lower part M1a. The second conductive member 20 and the semiconductor chip 60 are located above the lower part M1a. The lead part 23 contacts the upper surface of the protrusion M1b.

As illustrated in FIG. 8B, an upper die M2 is disposed above the bonded semiconductor chip 60 and the like. That is, the bonded semiconductor chip 60 and the like are located between the lower die M1 and the upper die M2.

The upper die M2 includes an upper part M2a, a protrusion M2b, and a protrusion M2c. The protrusion M2b and the protrusion M2c each extend downward from the upper part M2a. The first part 21, the connection plate 40, the semiconductor chip 60, and a portion of the first conductive member 10 are located below the upper part M2a. In other words, the first part 21, the connection plate 40, the semiconductor chip 60, and a portion of the first conductive member 10 are located in the space between the lower part M1a and the upper part M2a.

The lead part 23 contacts the lower surface of the protrusion M2b. That is, the lead part 23 is clamped by the protrusions M1b and M2b; and the position of the lead part 23 is fixed. The lower end of the protrusion M2c of the upper die M2 contacts the end portion 10ta of the upper surface 10t of the first conductive member 10. Similarly, another protrusion M2c (not illustrated) of the upper die M2 contacts the end portion 10tb of the upper surface 10t of the first conductive member 10 (see FIG. 2).

Then, the mold is closed. Namely, the bonded semiconductor chip 60 and the like are pressed onto the lower die M1 by the upper die M2. There are cases where the first conductive member 10 is moved downward by being pressed downward at the end portions 10ta and 10tb by the protrusion M2c of the upper die M2. As a result, for example, the lower surface 10b of the first conductive member 10 contacts the lower part Mia of the lower die M1. On the other hand, the lead part 23 has already been clamped by the lower die M1 (the protrusion M1b) and the upper die M2 (the protrusion M2b) and does not move. Thus, a force to pull the lead part 23 and the first conductive member 10 away from each other in the Z-direction is applied to the lead part 23 and the first conductive member 10. As a result, for example, delamination occurs at the second bonding member 52. For example, delamination occurs easily in the case where the Z-direction distance between the lead part 23 and the first conductive member 10 is short due to manufacturing fluctuation, etc.

Then, as illustrated in FIG. 8B, the resin part 70 is formed by injecting a resin material into the space between the lower part M1a and the upper part M2a. Subsequently, as illustrated in FIG. 8C, the lower die M1 and the upper die M2 are separated from the resin part 70; and the semiconductor device 100 is manufactured.

Thus, there are cases where the first conductive member 10 is pressed downward with respect to the lead part 23 in the manufacturing processes of the semiconductor device 100. In such a case, delamination of the second bonding member 52 may occur. Even when delamination of the second bonding member 52 occurs, increased on-resistance can be suppressed because the current easily flows through the first part 21 and the connection plate 40 above and below the second bonding member 52. For example, the defect rate of the product can be reduced thereby.

For example, the strength of the second bonding member 52 bonding the first part 21 and the connection plate 40 is less than the strength of the first bonding member 51 bonding the semiconductor chip 60 and the connection plate 40. As a result, for example, delamination occurs more easily in the second bonding member 52 than in the first bonding member 51. For example, the strength (the breakage resistance) of the bonding member may be confirmed using a tensile strength test. For example, in a test of a bonding member bonding two bonding members, one bonded body is pulled in the Z-direction to separate from the other bonded body; and the force when breakdown of the bonding member occurs is measured.

For example, the composition of the second bonding member 52 is different from the composition of the first bonding member 51. The strengths of the bonding members can be controlled thereby. For example, the strength of the second bonding member 52 can be set to be less than the strength of the first bonding member 51. As an example, the second bonding member 52 includes lead. The second bonding member 52 includes, for example, lead solder (Pb₅Sn). For example, the first bonding member 51 includes lead-free solder (Sn_{3.0}Ag_{0.5}Cu) and does not include lead. Or, the lead concentration (the concentration in % by mass) of the first bonding member 51 is less than the lead concentration (the concentration in % by mass) of the second bonding member 52.

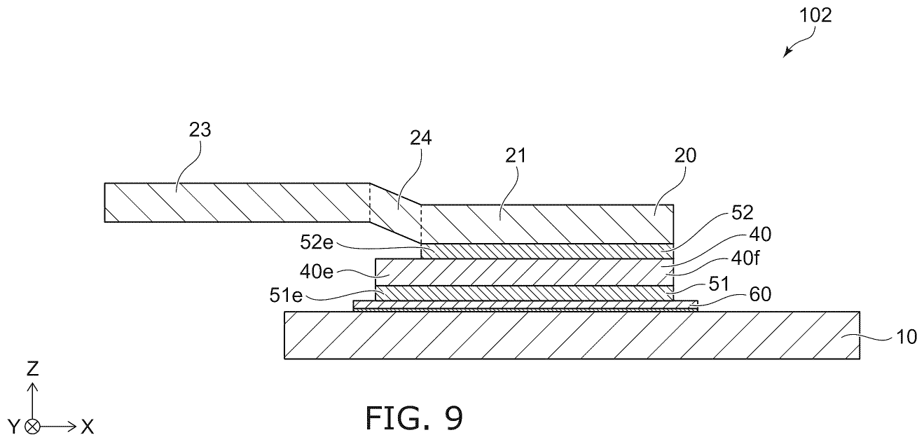

FIG. 9 is a schematic cross-sectional view illustrating a portion of another semiconductor device according to the first embodiment.

Similarly to FIG. 5, FIG. 9 is a cross section of a portion of the semiconductor device 102. The arrangement of the second bonding member 52 and the first part 21 of the semiconductor device 102 is different from that of the semiconductor device 100 illustrated in FIG. 5.

As illustrated in FIG. 9, the connection plate 40 includes an end portion 40e and an end portion 40f in the X-direction. The end portion 40e is the end portion at the lead part 23 side. In other words, the end portion 40e is positioned between the end portion 40f and at least a portion of the lead part 23 in the X-direction.

In the example, the second bonding member 52 does not contact the end portion 40e of the connection plate 40. For example, the solder that is used to form the second bonding member 52 is not coated up to the end portion 40e of the connection plate 40 at the lead part 23 side. As a result, for example, when a load is applied to the end portion 52e of the second bonding member 52, the load that is applied to an end portion 51e of the first bonding member 51 at the lead part 23 side can be suppressed. The delamination of the first bonding member 51 can be further suppressed.

The first bonding member 51 contacts the end portion 40e of the connection plate 40. For example, the solder that is used to form the first bonding member 51 is coated up to the end portion 40e of the connection plate 40 at the lead part 23 side. The delamination of the first bonding member 51 can be suppressed thereby.

The first bonding member 51 and the second bonding member 52 each contact the end portion 40f of the connection plate 40. That is, for example, the solder that is used to form the first bonding member 51 and the second bonding member 52 is coated up to the end portion 40f of the connection plate 40 at the side opposite to the lead part 23. As a result, the delamination of the first and second bonding members 51 and 52 at the side opposite to the lead part 23 can be suppressed.

For example, the X-direction width of the first bonding member 51 is substantially equal to the X-direction width of the connection plate 40. The X-direction width of the second bonding member 52 is less than the X-direction width of the connection plate 40. The X-direction width of the first part 21 may be substantially equal to the X-direction width of the second bonding member 52, or may be greater than the X-direction width of the second bonding member 52.

### Second embodiment

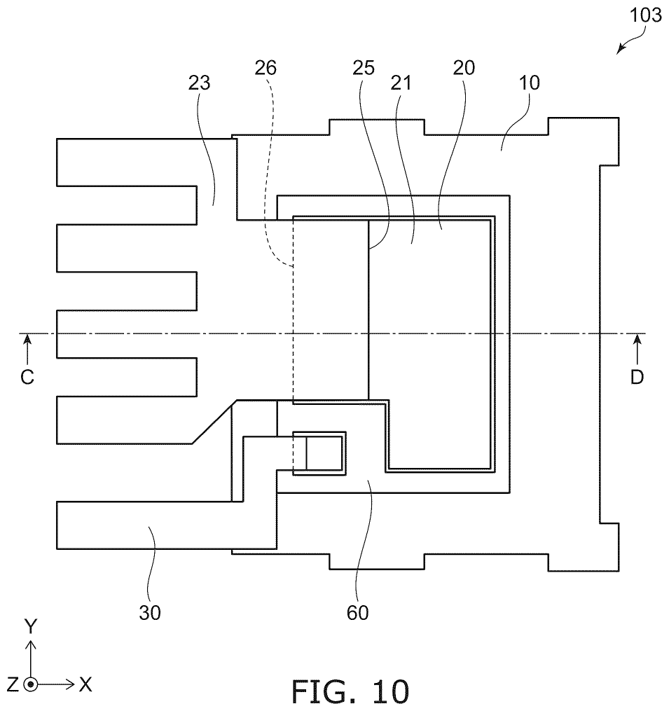

FIG. 10 is a schematic plan view illustrating a portion of a semiconductor device according to a second embodiment.

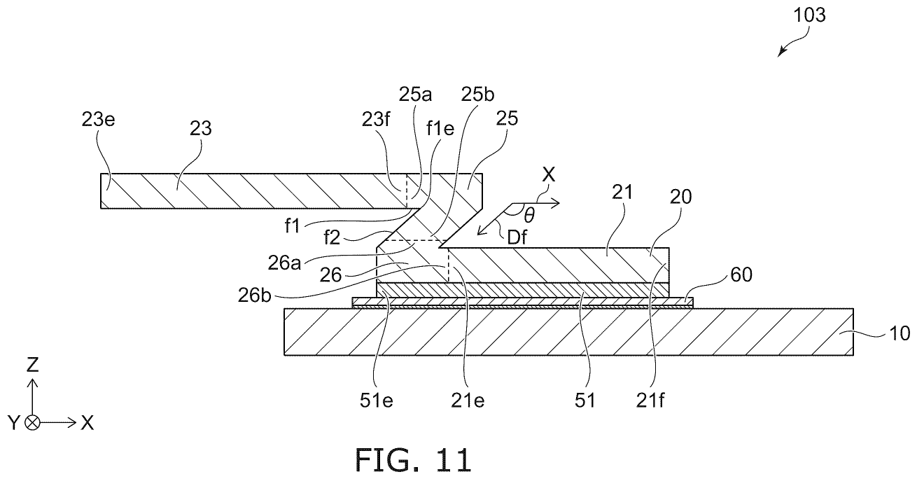

FIG. 11 is a schematic cross-sectional view illustrating a portion of the semiconductor device according to the second embodiment.

FIG. 11 shows a cross section along line C-D illustrated in FIG. 10.

Similarly to the semiconductor device 100, the semiconductor device 103 illustrated in FIGS. 10 and 11 also includes the first conductive member 10, the semiconductor chip 60, the first bonding member 51, the second conductive member 20, the third conductive member 30, and the resin part 70 (not illustrated). The shape of the second conductive member 20 of the semiconductor device 103 is different from that of the semiconductor device 100. The semiconductor device 103 does not include the connection plate 40 and the second bonding member 52.

In the example, the first bonding member 51 is positioned between the second conductive member 20 (the first part 21) and the semiconductor chip 60 and electrically connects the second conductive member 20 and the semiconductor chip 60. The first bonding member 51 contacts the first part 21 and the semiconductor chip 60. The resin part 70 (not illustrated) is formed by manufacturing processes similar to those described with reference to FIGS. 8A to 8C, and covers the second conductive member 20 (other than the lead part 23), the first bonding member 51, the semiconductor chip 60, and a portion of the first conductive member 10.

As illustrated in FIG. 11, the second conductive member 20 includes the first part 21, the lead part 23, a first folded part 25, and a second folded part 26.

The first part 21 extends in the X-direction, and includes the end portion 21e and an end portion 21f in the X-direction. The end portion 21e is the end portion at the lead part 23 side. In other words, the end portion 21e is positioned between the end portion 21f and at least a portion of the lead part 23 in the X-direction.

The lead part 23 includes a distal portion 23e and a back end portion 23f, and extends in the X-direction. The back end portion 23f is separated from the distal portion 23e in the X-direction. The back end portion 23f is positioned between the distal portion 23e and the first part 21 in the X-direction.

The first folded part 25 includes an end portion 25a and an end portion 25b. The end portion 25b is separated from the end portion 25a. The end portion 25a is continuous from the back end portion 23f of the lead part 23. The first folded part 25 is folded from the X-direction toward a folding direction Df. That is, the first folded part 25 extends from the end portion 25a in the X-direction, is folded toward the folding direction Df, and extends to the end portion 25b. For example, at least a portion of the first folded part 25 is arranged with (overlaps) a portion of the first part 21, a portion of the semiconductor chip 60, and a portion of the first bonding member 51 in the Z-direction. In the X-direction, the first folded part 25 is positioned between the lead part 23 and the X-direction center of the first bonding member 51.

The second folded part 26 includes an end portion 26a and an end portion 26b. The end portion 26b is separated from the end portion 26a. The end portion 26a is continuous from the end portion 25b. The second folded part 26 is folded from the folding direction Df toward the X-direction. That is, the second folded part 26 extends from the end portion 26a in the folding direction Df, is folded toward the X-direction, and extends to the end portion 26b. The end portion 21e of the first part 21 is continuous from the end portion 26b. For example, at least a portion of the second folded part 26 is arranged with (overlaps) a portion of the lead part 23, a portion of the semiconductor chip 60, and a portion of the first bonding member 51 in the Z-direction. At least a portion of the second folded part 26 is positioned further toward the distal portion 23e side of the lead part 23 than the first folded part 25.

As illustrated in FIG. 11, an angle e between the X-direction and the folding direction Df is, for example, greater than 90° and not more than 180°.

In the example, the cross-sectional shape of the second conductive member 20 has a Z-shape. For example, as illustrated in FIG. 11, the first folded part 25 includes a first surface f1 and a second surface f2. The first surface f1 is along the X-direction. The second surface f2 extends in the folding direction Df from an X-direction end f1e of the first surface f1. The angle between the first surface f1 and the second surface f2 at the end f1e is acute. Similarly, the second folded part 26 also is folded to have an acute angle.

According to the embodiment, defects of the semiconductor device 100 such as increased on-resistance can be suppressed by suppressing delamination of the first bonding member 51. The risk of occurrence of defects such as increased on-resistance, etc., can be reduced.

As described above, the second conductive member 20 includes the first folded part 25 and the second folded part 26. When the first conductive member 10 is pressed by a mold with the position of the lead part 23 in a fixed state, the load is absorbed by the first and second folded parts 25 and 26. The load that is applied to the end portion 51e of the first bonding member 51 can be reduced thereby. Delamination of the first bonding member 51 can be suppressed. The risk of occurrence of defects such as increased on-resistance, etc., can be reduced.

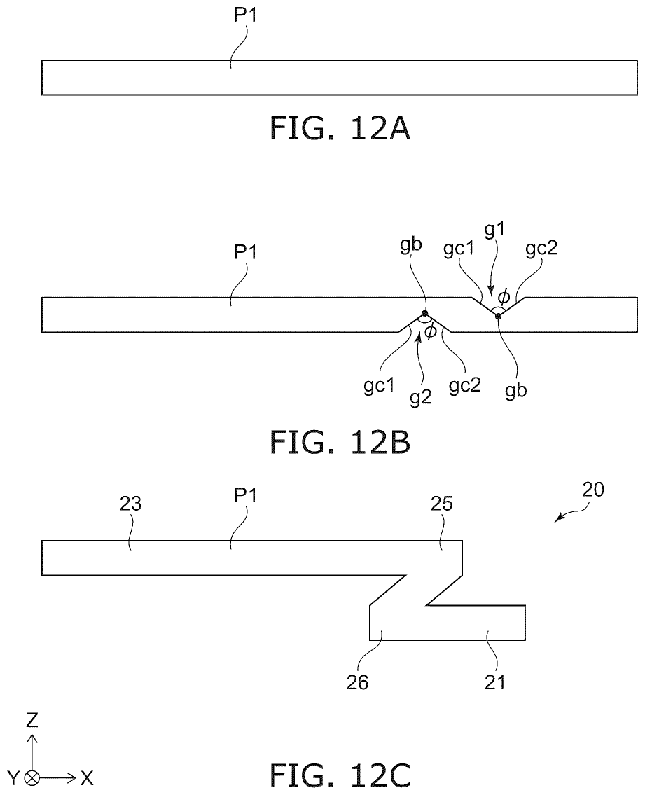

FIGS. 12A to 12C are schematic cross-sectional views illustrating manufacturing processes of the second conductive member according to the embodiment.

For example, the second conductive member 20 is one metal plate P1 that is bent at the first and second folded parts 25 and 26. That is, the lead part 23, the first folded part 25, the second folded part 26, and the first part 21 are one continuous conductive member, and are formed of the same material.

For example, one metal plate P1 is prepared as in FIG. 12A. As in FIG. 12B, a groove g1 and a groove g2 that extend in the Y-direction are provided respectively in the upper surface and lower surface of the metal plate P1. The groove g1 and the groove g2 each include a bottom gb, and two side surfaces, i.e., a side surface gc1 and a side surface gc2, that cross at the bottom gb. An angle ϕ between the side surface gc1 and the side surface gc2 is greater than 90°.

As illustrated in FIG. 12C, the first folded part 25 is formed by bending the metal plate P1 at the groove g2. The second folded part 26 is formed by bending the metal plate P1 at the groove g1.

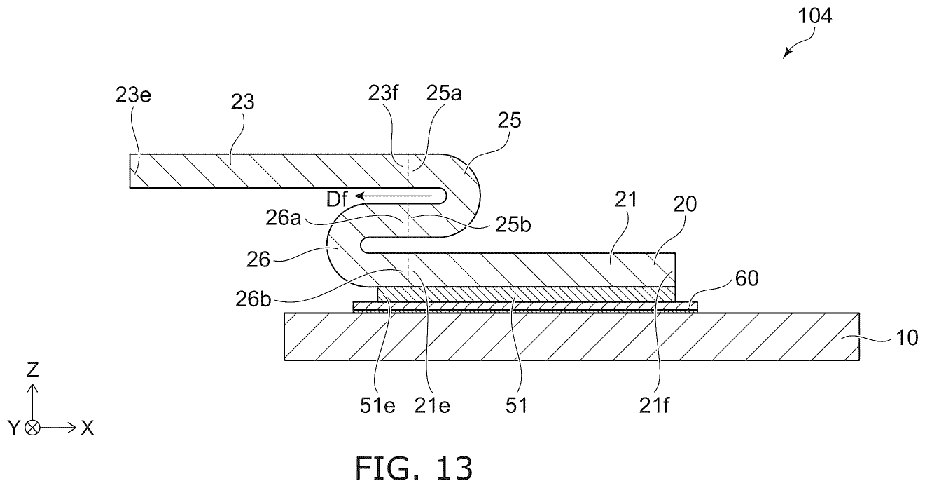

FIG. 13 is a schematic cross-sectional view illustrating a portion of another semiconductor device according to the second embodiment.

The shape of the second conductive member 20 of the semiconductor device 104 illustrated in FIG. 13 is different from that of the semiconductor device 103.

In the example, the cross-sectional shape of the second conductive member 20 is S-shaped. For example, the first folded part 25 has a curved shape that is convex in the X-direction. The second folded part 26 has a curved shape that is convex in the opposite direction of the X-direction.

In the example, the folding direction Df is the opposite direction of the X-direction. That is, the angle between the X-direction and the folding direction Df is 180°.

In the semiconductor device 104 as well, the load received from the mold is absorbed by the first and second folded parts 25 and 26. The load that is applied to the end portion 51e of the first bonding member 51 can be reduced thereby. Delamination of the first bonding member 51 can be suppressed. The risk of occurrence of defects such as increased on-resistance, etc., can be reduced.

Embodiments may include the following configurations.

### Configuration 1

A semiconductor device, comprising:
a first conductive member;
a second conductive member including
   a first part separated from the first conductive member in a first direction, and
   a second part extending from an end portion of the first part in a second direction crossing the first direction, the second part including a lead part;
a semiconductor chip located between the first part and the first conductive member in the first direction, the semiconductor chip being electrically connected with the first conductive member;
a connection plate located between the semiconductor chip and the first part in the first direction, the connection plate being conductive;
a first bonding member positioned between the semiconductor chip and the connection plate, the first bonding member electrically connecting the semiconductor chip and the connection plate, the first bonding member being conductive;
a second bonding member positioned between the first part and the connection plate, the second bonding member electrically connecting the first part and the connection plate, the second bonding member being conductive; and
a resin part covering the semiconductor chip, the connection plate, and the first part,
the resin part not covering a portion of the lead part and a portion of the first conductive member.

### Configuration 2

The device according to Configuration 1, wherein
the connection plate includes an end portion in the second direction,
the end portion of the connection plate is positioned at the lead part side, and
the second bonding member does not contact the end portion of the connection plate.

### Configuration 3

The device according to Configuration 2, wherein
the first bonding member contacts the end portion of the connection plate.

### Configuration 4

The device according to any one of Configurations 1 to 3, wherein
a strength of the second bonding member is less than a strength of the first bonding member.

### Configuration 5

The device according to any one of Configurations 1 to 4, wherein
a composition of the second bonding member is different from a composition of the first bonding member.

### Configuration 6

The device according to Configuration 5, wherein
the second bonding member includes lead, and
the first bonding member does not include lead, or a lead concentration of the first bonding member is less than a lead concentration of the second bonding member.

### Configuration 7

A semiconductor device, comprising:
a first conductive member;
a second conductive member including
   a first part separated from the first conductive member in a first direction, the first part extending in a second direction crossing the first direction,
   a lead part extending in the second direction, the lead part including
      a distal portion, and
      a back end portion separated from the distal portion in the second direction,
   a first folded part continuous from the back end portion of the lead part, the first folded part being folded from the second direction toward a folding direction, at least a portion of the first folded part being arranged with the first part in the first direction, and
   a second folded part continuous from the first folded part, the second folded part being folded from the folding direction toward the second direction, the second folded part extending to an end portion in the second direction of the first part;
a semiconductor chip located between the first part and the first conductive member in the first direction, the semiconductor chip being electrically connected with the first conductive member; and
a bonding member located between the semiconductor chip and the first part, the bonding member contacting the semiconductor chip and the first part and electrically connecting the semiconductor chip and the first part, the bonding member being conductive.

### Configuration 8

The device according to Configuration 7, wherein
the first folded part has a curved shape, and
the curved shape is convex in the second direction.

### Configuration 9

The device according to Configuration 7, wherein t
he first folded part includes:
   a first surface along the second direction; and
   a second surface extending in the folding direction from an end in the second direction of the first surface, and
an angle between the first surface and the second surface is acute.

### Configuration 10

The device according to any one of Configurations 7 to 9, wherein
the second conductive member is one metal plate bent at the first and second folded parts.

According to embodiments, a semiconductor device can be provided in which defects can be suppressed.

In this specification, being “electrically connected” includes not only the case of being connected in direct contact, but also the case of being connected via another conductive member, etc.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Additionally, the embodiments described above can be combined mutually.

What is claimed is:

1. A semiconductor device, comprising:
a first conductive member;
a second conductive member including
a first part separated from the first conductive member in a first direction, and
a second part extending from an end portion of the first part in a second direction crossing the first direction, the second part including a lead part;
a semiconductor chip located between the first part and the first conductive member in the first direction, the semiconductor chip being electrically connected with the first conductive member;
a connection plate located between the semiconductor chip and the first part in the first direction, the connection plate being conductive;
a first bonding member positioned between the semiconductor chip and the connection plate, the first bonding member electrically connecting the semiconductor chip and the connection plate, the first bonding member being conductive;
a second bonding member positioned between the first part and the connection plate, the second bonding member electrically connecting the first part and the connection plate, the second bonding member being conductive; and
a resin part covering the semiconductor chip, the connection plate, and the first part,
the resin part not covering a portion of the lead part and a portion of the first conductive member.

2. The device according to claim 1, wherein
the connection plate includes an end portion in the second direction,
the end portion of the connection plate is positioned at the lead part side, and
the second bonding member does not contact the end portion of the connection plate.

3. The device according to claim 2, wherein
the first bonding member contacts the end portion of the connection plate.

4. The device according to claim 1, wherein
a strength of the second bonding member is less than a strength of the first bonding member.

5. The device according to claim 1, wherein
a composition of the second bonding member is different from a composition of the first bonding member.

6. The device according to claim 5, wherein
the second bonding member includes lead, and
the first bonding member does not include lead, or a lead concentration of the first bonding member is less than a lead concentration of the second bonding member.

7. A semiconductor device, comprising:
a first conductive member;
a second conductive member including
a first part separated from the first conductive member in a first direction, the first part extending in a second direction crossing the first direction,
a lead part extending in the second direction, the lead part including
a distal portion, and
a back end portion separated from the distal portion in the second direction,
a first folded part continuous from the back end portion of the lead part, the first folded part being folded from the second direction toward a folding direction, at least a portion of the first folded part being arranged with the first part in the first direction, and
a second folded part continuous from the first folded part, the second folded part being folded from the folding direction toward the second direction, the second folded part extending to an end portion in the second direction of the first part;
a semiconductor chip located between the first part and the first conductive member in the first direction, the semiconductor chip being electrically connected with the first conductive member; and
a bonding member located between the semiconductor chip and the first part, the bonding member contacting the semiconductor chip and the first part and electrically connecting the semiconductor chip and the first part, the bonding member being conductive.

8. The device according to claim 7, wherein
the first folded part has a curved shape, and
the curved shape is convex in the second direction.

9. The device according to claim 7, wherein
the first folded part includes:
a first surface along the second direction; and
a second surface extending in the folding direction from an end in the second direction of the first surface, and
an angle between the first surface and the second surface is acute.

10. The device according to claim 7, wherein
the second conductive member is one metal plate bent at the first and second folded parts.
